(19) United States
(12) Patent Application Publication
(10) Pub. No.: US 2025/0201521 A1
(43) Pub. Date: Jun. 19, 2025

(54) SUBSTRATE SUPPORT ASSEMBLY, PLASMA CONTROL METHOD, AND PLASMA PROCESSING APPARATUS

(71) Applicant: SEMES CO., LTD., Cheonan-si (KR)

(72) Inventors: Dae Hyun YOO, Cheonan-si (KR); Ja Myung GU, Cheonan-si (KR); Jae Hong MIN, Cheonan-si (KR)

(73) Assignee: SEMES CO., LTD., Cheonan-si (KR)

(21) Appl. No.: 18/914,337

(22) Filed: Oct. 14, 2024

(30) Foreign Application Priority Data
Dec. 13, 2023 (KR) 10-2023-0181059

(51) Int. Cl. H01J 37/32

(52) U.S. Cl. CPC H01J 37/32183; H01J 37/32642; H01J 37/32697; H01J 37/32715; H01J 2237/2007

(57) ABSTRACT

Disclosed are a substrate support assembly, a plasma control method, and a plasma processing apparatus capable of controlling plasma distribution using harmonic components of a radio-frequency (RF) signal. The substrate support assembly configured to support a substrate in the plasma processing apparatus includes an electrostatic chuck configured to support the substrate using electrostatic force, an edge ring surrounding the electrostatic chuck, an insulating ring disposed beneath the edge ring, an edge electrode disposed in the insulating ring, a harmonic impedance tuning circuit connected to the edge electrode, and an edge impedance control circuit connected to the harmonic impedance tuning circuit. The harmonic impedance tuning circuit includes a band-stop filter having a resonance frequency equal to or higher than a harmonic frequency of a source frequency of an RF signal.

### CROSS-REFERENCE TO THE RELATED APPLICATION

The present application claims priority to and the benefit of Korean Patent Application No. 10-2023-0181059, filed on Dec. 13, 2023, in the Korean Intellectual Property Office, the entire disclosure of which is incorporated herein by reference.

### BACKGROUND

### Technical Field

The present disclosure relates to a substrate support assembly configured to support a substrate, a plasma control method performed by the substrate support assembly, and a plasma processing apparatus including the substrate support assembly.

### Description of the Related Art

A semiconductor manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

Processes using plasma, for example, etching and deposition, are widely used in the semiconductor manufacturing process. A plasma processing process is performed in such a manner that a substrate is seated at a lower portion in a plasma processing space, fluid for plasma processing is supplied, and a radio-frequency (RF) signal is applied by electrodes located at an upper portion and a lower portion in the plasma processing space.

Harmonic components of the RF signal, i.e., frequency components corresponding to N times the frequency of the RF signal (“N” being an integer greater than or equal to 2), affect plasma distribution in a chamber. Generally, a filter is employed in order to remove such harmonic components.

### SUMMARY

It is an object of the present disclosure to provide a substrate support assembly, a plasma control method, and a plasma processing apparatus capable of controlling plasma distribution using harmonic components of a radio-frequency (RF) signal without removing the harmonic components.

In accordance with an aspect of the present disclosure, the above and other objects can be accomplished by the provision of a substrate support assembly configured to support a substrate in a plasma processing apparatus, the substrate support assembly including an electrostatic chuck configured to support the substrate using electrostatic force, an edge ring surrounding the electrostatic chuck, an insulating ring disposed beneath the edge ring, an edge electrode disposed in the insulating ring, a harmonic impedance tuning circuit connected to the edge electrode, and an edge impedance control circuit connected to the harmonic impedance tuning circuit. The harmonic impedance tuning circuit includes a band-stop filter having a resonance frequency equal to or higher than a harmonic frequency of a source frequency of an RF signal.

In one embodiment of the present disclosure, the resonance frequency of the harmonic impedance tuning circuit may be set to be equal to or higher than a third-order harmonic frequency.

In one embodiment of the present disclosure, the harmonic impedance tuning circuit may include a first inductor connected to a path between the edge electrode and the edge impedance control circuit, and may include a second inductor and a variable capacitor connected between the ground and a node between the first inductor and the edge electrode.

In one embodiment of the present disclosure, the second inductor and the variable capacitor may be connected in series to each other.

In one embodiment of the present disclosure, the first inductor may have inductance set to 10 nH or less, the second inductor may have inductance set to 10 nH or less, and the variable capacitor may have capacitance set to 10 pF or less.

In one embodiment of the present disclosure, the variable capacitor may be configured as a vacuum variable capacitor (VVC).

In one embodiment of the present disclosure, the variable capacitor may be configured to change the pass rates and the phases of the RF signal and first-order and second-order harmonic components of the RF signal.

In accordance with another aspect of the present disclosure, there is provided a plasma control method performed by a substrate support assembly in a plasma processing apparatus, the plasma control method including controlling plasma distribution in an edge area using the edge impedance control circuit and controlling plasma distribution in a central area using the harmonic impedance tuning circuit.

In accordance with a further aspect of the present disclosure, there is provided a plasma processing apparatus including a process chamber including a processing space defined therein, a substrate support assembly configured to support a substrate in the processing space, a gas supply member configured to supply a process gas to the processing space, and an RF power supply configured to supply an RF signal so as to excite the process gas to a plasma state. The substrate support assembly includes an electrostatic chuck configured to support the substrate using electrostatic force, an edge ring surrounding the electrostatic chuck, an insulating ring disposed beneath the edge ring, an edge electrode disposed in the insulating ring, a harmonic impedance tuning circuit connected to the edge electrode, and an edge impedance control circuit connected to the harmonic impedance tuning circuit. The harmonic impedance tuning circuit includes a band-stop filter having a resonance frequency equal to or higher than a third-order harmonic frequency of a source frequency of the RF power supply.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view schematically showing the structure of a plasma processing apparatus according to the present disclosure;

FIG. 2 shows the configuration of a substrate support assembly for control of plasma in the plasma processing apparatus according to the present disclosure;

FIG. 3 shows the configuration of a harmonic impedance tuning circuit;

FIG. 4 is a flowchart showing a plasma control method performed by the substrate support assembly in the plasma processing apparatus according to the present disclosure;

FIG. 5 shows plasma distribution in accordance with change in the impedance of the harmonic impedance tuning circuit of the present disclosure;

FIG. 6 shows a power transmission rate in accordance with change in the impedance of the harmonic impedance tuning circuit of the present disclosure;

FIG. 7 shows a phase in accordance with change in the impedance of the harmonic impedance tuning circuit of the present disclosure; and

FIG. 8 shows a result of measuring a reactance component of the harmonic impedance tuning circuit in accordance with frequency.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Hereinafter, a substrate support assembly 20 configured to support a substrate W, a plasma control method performed by the substrate support assembly 20, and a plasma processing apparatus 1 including the substrate support assembly 20 according to the present disclosure will be described. The plasma processing apparatus 1 is equipment for performing plasma processing (e.g., dry etching) on the substrate W. When the substrate W is loaded in the plasma processing apparatus 1, high-frequency power is applied to an upper electrode and a lower electrode to generate an electromagnetic field, and a process gas supplied to the substrate W transitions to a plasma state due to the electromagnetic field, and reacts with a specific material of the substrate W. The substrate W having undergone plasma processing for a certain period of time is discharged to the outside of the plasma processing apparatus 1, and subsequent processing processes are performed.

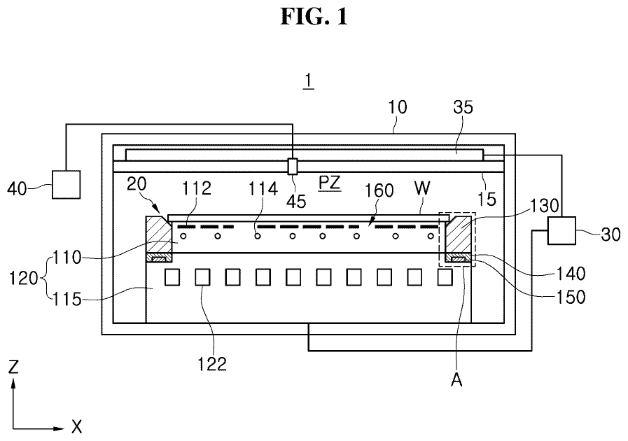

FIG. 1 is a view schematically showing the structure of the plasma processing apparatus 1 according to the present disclosure. The plasma processing apparatus 1 according to the present disclosure includes a chamber 10 including a plasma processing space PZ for a substrate W defined therein, a substrate support assembly 20 configured to support the substrate W, an upper electrode 35 configured to generate plasma in the plasma processing space PZ, a window 15 configured to isolate the upper electrode 35 from the plasma processing space PZ, a radio-frequency (RF) power supply 30 configured to supply power to the upper electrode 35, a gas supply member 45 configured to supply a process gas to the plasma processing space PZ, and a gas source 40 configured to supply the process gas to the gas supply member 45. In addition, although not specifically shown in the drawings, the plasma processing apparatus 1 may include an opening/closing door configured to expose or shield the interior of the chamber 10 to or from the outside space and a baffle configured to discharge by-products generated by plasma processing and gas to the outside.

The chamber 10 includes the plasma processing space PZ for the substrate W defined therein, and components for plasma processing are mounted in the chamber 10. The window 15, the upper electrode 35, and the gas supply member 45 are disposed at an upper portion in the chamber 10, and the substrate support assembly 20 is disposed at a lower portion in the chamber 10.

The window 15 isolates an upper space in which the upper electrode 35 is located from the plasma processing space PZ. The window 15 is formed to cover the upper side of the chamber 10 in order to seal the inner space in the chamber 10. The window 15 may be formed in a plate shape (e.g., disc shape), and may be made of an insulative material (e.g., alumina (Al₂O₃)).

The substrate support assembly 20 is disposed at a lower portion in the chamber 10, and supports the substrate W using electrostatic force. The substrate support assembly 20 may be provided therein with an electrode 112 to strongly attract the substrate W to the substrate support assembly 20 with electrostatic force. The substrate support assembly 20 may function as a lower electrode for generation of plasma.

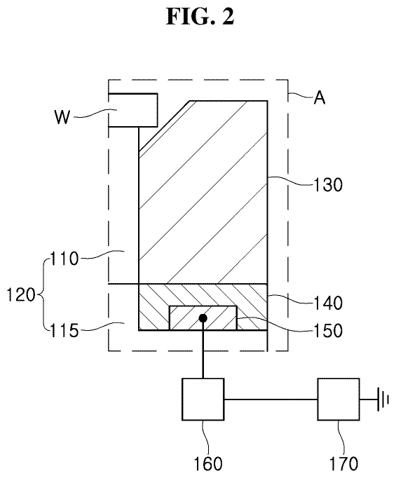

The substrate support assembly 20 includes an electrostatic chuck 120 configured to support the substrate W using electrostatic force, an edge ring 130 surrounding the electrostatic chuck 120, an insulating ring 140 disposed beneath the edge ring 130, an edge electrode 150 disposed in the insulating ring 140, a harmonic impedance tuning circuit 160 connected to the edge electrode 150, and an edge impedance control circuit 170 connected to the harmonic impedance tuning circuit 160 (refer to FIG. 2).

The electrostatic chuck 120 includes a ceramic puck 110 configured to allow the substrate W to be plasma-processed to be seated thereon and including a heater 114 mounted therein and a base plate 115 configured to support a lower side of the ceramic puck 110 and including a cooling path 122 formed therein to allow cooling fluid to flow therethrough.

The ceramic puck 110 is a structure configured to support the substrate W from below, and is provided therein with the electrode 112 and the heater 114. The ceramic puck 110 may be made of a ceramic material (e.g., quartz).

The base plate 115 is formed in a disc shape and is made of metal (e.g., Al). The base plate 115 may include a lower region having a predetermined diameter and an upper region having a smaller diameter than the lower region. The cooling path 122 may be formed in the lower region of the base plate 115. The upper region of the base plate 115 may be coupled to the ceramic puck 110. That is, the base plate 115 may have a shape in which the lower region protrudes. The edge ring 130 for control of plasma on an edge portion of the substrate W may be provided on the protruding portion of the base plate 115.

A coating layer made of alumina (Al₂O₃) may be formed on an outer surface of the base plate 115. The coating layer prevents the base plate 115 made of metal (e.g., Al) from being exposed to the external environment, particularly, plasma. In addition, a bonding layer is formed between the ceramic puck 110 and the base plate 115 in order to bond the ceramic puck 110 to the base plate 115.

The RF power supply 30 applies power to the upper electrode and to the lower electrode provided at the substrate support assembly 20. The RF power supply 30 may be configured to control the characteristics of plasma. The RF power supply 30 may be configured to control, for example, ion bombardment energy. Although the RF power supply 30 is illustrated in FIG. 1 as being connected both to the upper electrode 35 and to the substrate support assembly 20, the disclosure is not limited thereto. An upper power supply connected to the upper electrode 35 and a lower power supply connected to the substrate support assembly 20 may be provided separately from each other. The upper power supply may include a plurality of power supplies, and the lower power supply may include a plurality of power supplies. In a case in which the upper power supply is provided in plural, a matching network electrically connected to the plurality of upper power supplies may be provided at the plasma processing apparatus 1. The matching network may match frequency powers having different magnitudes input from the respective upper power supplies and the lower power supply, and may apply the matched frequency powers to the upper electrode 35 and the substrate support assembly 20. In addition, impedance matching circuits (not shown) may be provided on transmission lines connecting the upper power supply and the lower power supply to the upper electrode 35 and the substrate support assembly 20 for the purpose of impedance matching.

The upper electrode 35 generates plasma from gas remaining in the plasma processing space PZ. Here, the plasma processing space PZ refers to a space located above the substrate support assembly 20 in the inner space in the chamber 10. The upper electrode 35 may generate plasma in accordance with an inductively coupled plasma method or a capacitively coupled plasma method. The upper electrode 35 may generate an electromagnetic field from the power supplied from the RF power supply 30. A matching circuit for impedance matching may be provided between the upper electrode 35 and the RF power supply 30.

The gas source 40 supplies an etching gas used to process the substrate W as the process gas. The gas source 40 may supply a gas containing a fluorine component (e.g., gas containing SF₆ or CF₄) to the gas supply member 45 as an etching gas.

The gas supply member 45 may be mounted at an upper portion in the chamber 10 so as to face the substrate support assembly 20 in a vertical direction Z. The gas supply member 45 may include a plurality of gas spray holes formed therein in order to spray a gas to the interior of the chamber 10. The gas supply member 45 may be formed to have a larger diameter than the substrate support assembly 20 in a horizontal direction X. The gas supply member 45 may be a showerhead including a plurality of gas spray holes formed therein. Further, the gas supply member 45 may be a structure including one or more gas supply nozzles. The gas supply member 45 may be made of a material containing a silicon component or a material containing a metal component.

FIG. 2 shows the configuration of the substrate support assembly 20 for control of plasma in the plasma processing apparatus 1 according to the present disclosure. FIG. 2 is an enlarged view of an edge area A of the substrate support assembly 20 shown in FIG. 1.

Referring to FIG. 2, the edge ring 130 is disposed in the edge area of the ceramic puck 110. The upper surface of the edge ring 130 may have a sloped or stepped portion so that the height of the outer side portion thereof is greater than the height of the inner side portion thereof. The edge ring 130 serves to expand an electric-field formation area so that the substrate W is placed at the center of the area in which plasma is formed. Accordingly, plasma may be uniformly formed over the entire area of the substrate W, and thus the entire area of the substrate W may be uniformly etched.

The insulating ring 140 is disposed beneath the edge ring 130. The edge electrode 150 is provided in the insulating ring 140. The edge electrode 150 may be electrically connected to the harmonic impedance tuning circuit 160 and the edge impedance control circuit 170. The edge electrode 150 may be connected to the harmonic impedance tuning circuit 160 and the edge impedance control circuit 170 via an RF transmission line.

The harmonic impedance tuning circuit 160 is a circuit that controls plasma in the central area in the processing space PZ. As will be described later, the harmonic impedance tuning circuit 160 may control plasma distribution in the central area through impedance variation. The edge impedance control circuit 170 is a circuit that controls plasma in the edge area in the processing space PZ. The edge impedance control circuit 170 may control plasma distribution in the edge area of the substrate W by controlling the overall impedance of the RF path connected from the electrostatic chuck 120 to the edge ring 130 or to the edge impedance control circuit 170.

When plasma is generated by an RF signal (e.g., 60 MHz), harmonic components (e.g., 120 MHz and 180 MHz) of the RF signal may be coupled to the edge ring 130. The harmonic impedance tuning circuit 160 may control plasma distribution by the harmonic components by varying impedance while blocking harmonic components of a predetermined order or higher (e.g., 200 MHz or higher). In particular, the harmonic impedance tuning circuit 160 may control plasma distribution in the central area of the substrate W, which is mainly affected by the harmonic components.

The harmonic impedance tuning circuit 160 includes a band-stop filter having a resonance frequency (e.g., 240 MHz) equal to or higher than the harmonic frequency of the source frequency (e.g., 60 MHz) of the RF power supply 30. The resonance frequency of the harmonic impedance tuning circuit 160 may be set to be equal to or higher than the third-order harmonic frequency (e.g., 240 MHZ). The harmonic impedance tuning circuit 160 may block the third or higher-order harmonic frequency components (e.g., 240 MHz or higher), and may pass the source frequency (e.g., 60 MHz) and the first-order and second-order harmonic frequency components (e.g., 120 MHz and 180 MHz) of the RF signal. The harmonic impedance tuning circuit 160 may control plasma distribution by changing the loss rates and the phases of the source frequency (e.g., 60 MHZ) and the first-order and second-order harmonic frequency components (e.g., 120 MHz and 180 MHz) of the RF signal.

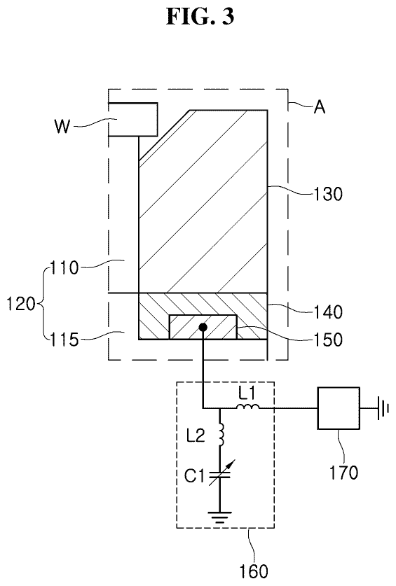

FIG. 3 shows the configuration of the harmonic impedance tuning circuit 160. Referring to FIG. 3, the harmonic impedance tuning circuit 160 includes a first inductor L1 connected to a path between the edge electrode 150 and the edge impedance control circuit 170, and includes a second inductor L2 and a variable capacitor C1, which are connected between the ground and a node B between the first inductor L1 and the edge electrode 150. The second inductor L2 and the variable capacitor C1 are connected in series to each other. The impedance of the harmonic impedance tuning circuit 160 may be changed by adjusting the element values of the first inductor L1, the second inductor L2, and the variable capacitor C1. The plasma distribution may be controlled by adjusting the impedance of the harmonic impedance tuning circuit 160. The harmonic impedance tuning circuit 160 includes an inductor-capacitor (LC) series band-stop filter. In this case, it is preferable that the resonance frequency (cutoff frequency) of the band-stop filter be set to be equal to or higher than the third-order harmonic frequency. That is, the resonance frequency may be set around 240 MHz, which is the third-order harmonic frequency on the basis of the source frequency of 60 MHz.

In one embodiment, the inductance of the first inductor L1 may be set to 10 nH or less, the inductance of the second inductor L2 may be set to 10 nH or less, and the capacitance of the variable capacitor C1 may be set to 10 pF or less. The variable capacitor C1 may be controlled to have capacitance between 3 pF and 10 pF. The variable capacitor C1 may be configured as a vacuum variable capacitor (VVC). The VVC is a capacitor that is capable of being adjusted in capacitance by an operation knob.

According to the embodiment of the present disclosure, the impedance of the harmonic impedance tuning circuit 160 may be adjusted by adjusting the capacitance of the variable capacitor C1. The plasma distribution in the central area of the substrate W may be controlled by adjusting the impedance of the harmonic impedance tuning circuit 160. The variable capacitor C1 is configured to change the pass rates and the phases of the RF signal and the first-order and second-order harmonic components of the RF signal. The plasma distribution may be controlled by changing the pass rates and the phases of the RF signal and the first-order and second-order harmonic components of the RF signal.

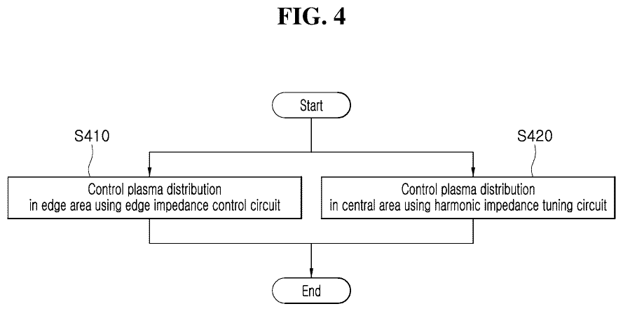

FIG. 4 is a flowchart showing a plasma control method performed by the substrate support assembly 20 in the plasma processing apparatus 1 according to the present disclosure. The plasma control method shown in FIG. 4 may be performed for initial setting of the plasma processing apparatus 1 before processing of the substrate W.

The plasma control method according to the present disclosure includes a step of controlling plasma distribution in the edge area using the edge impedance control circuit 170 (S410) and a step of controlling plasma distribution in the central area using the harmonic impedance tuning circuit 160 (S420).

In step S410, the plasma distribution in the edge area of the substrate W may be controlled by tuning the element values of the edge impedance control circuit 170. The edge impedance control circuit 170 is a circuit that controls plasma in the edge area in the processing space. The edge impedance control circuit 170 may control plasma distribution in the edge area of the substrate W by controlling the overall impedance of the RF path connected from the electrostatic chuck 120 to the edge ring 130 or to the edge impedance control circuit 170.

In step S420, the plasma distribution in the central area of the substrate W may be controlled by tuning the element values of the harmonic impedance tuning circuit 160. The harmonic impedance tuning circuit 160 includes a band-stop filter having a resonance frequency (e.g., 240 MHz) equal to or higher than the harmonic frequency of the source frequency (e.g., 60 MHZ) of the RF power supply 30. The resonance frequency of the harmonic impedance tuning circuit 160 may be set to be equal to or higher than the third-order harmonic frequency (e.g., 240 MHz). The harmonic impedance tuning circuit 160 may block the third or higher-order harmonic frequency components (e.g., 240 MHz or higher), and may pass the source frequency (e.g., 60 MHz) and the first-order and second-order harmonic frequency components (e.g., 120 MHz and 180 MHz) of the RF signal. The harmonic impedance tuning circuit 160 may control plasma distribution in the central area by changing the loss rates and the phases of the source frequency (e.g., 60 MHz) and the first-order and second-order harmonic frequency components (e.g., 120 MHz and 180 MHz) of the RF signal.

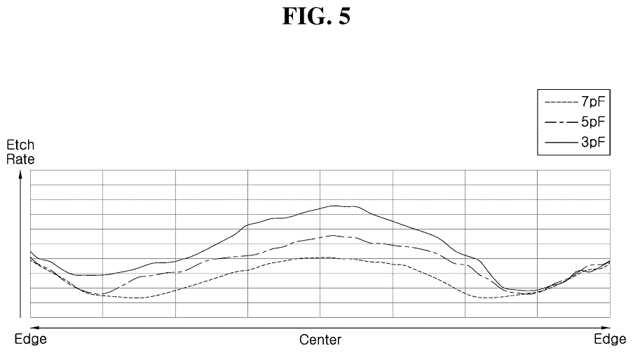

FIG. 5 shows plasma distribution in accordance with change in the impedance of the harmonic impedance tuning circuit 160 of the present disclosure. FIG. 5 shows plasma distribution when the variable capacitor C1 of the harmonic impedance tuning circuit 160 is set to 3 pF, 5 pF, and 7 pF, respectively. As shown in FIG. 5, it is confirmed that the plasma distribution in the central area of the substrate W is controlled by adjusting the impedance of the harmonic impedance tuning circuit 160.

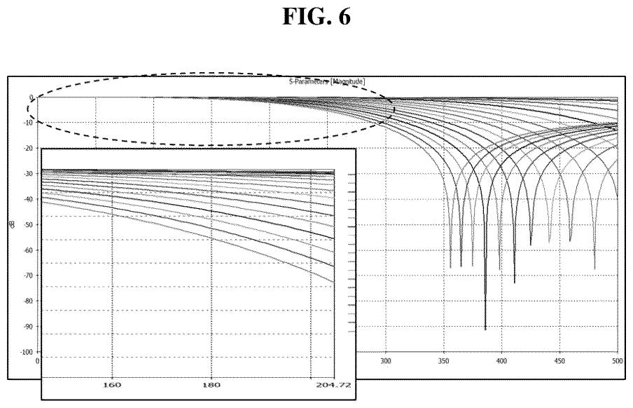

FIG. 6 shows a power transmission rate (loss rate) in accordance with change in the impedance of the harmonic impedance tuning circuit 160 of the present disclosure. FIG. 6 shows a power transmission rate (S-parameter) when the source frequency is 60 MHz, the inductance of each of the first inductor L1 and the second inductor L2 is 10 nH, and the capacitance of the variable capacitor C1 is adjusted in several stages between 3 pF and 10 pF. In FIG. 6, the vertical axis represents a power transmission rate (dB), and the horizontal axis represents frequency (MHz). The curves shown in FIG. 6 indicate simulation results for the power transmission rate in accordance with the capacitance value of the variable capacitor C1. Referring to FIG. 6, it is confirmed that the power transmission rate may be adjusted in accordance with change in the impedance of the harmonic impedance tuning circuit 160. In addition, it is confirmed that the resonance point of the band-stop filter is set to a frequency equal to or higher than a harmonic frequency of a predetermined order or higher (e.g., 200 MHz).

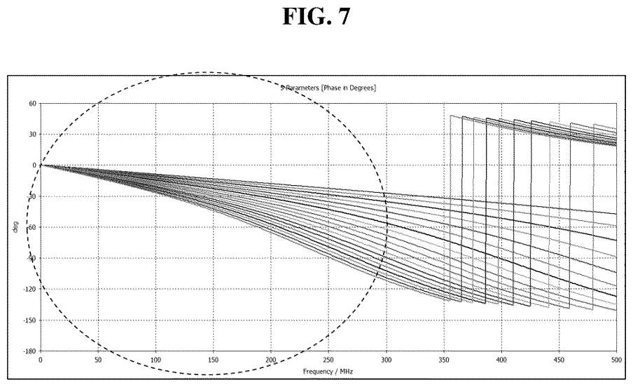

FIG. 7 shows a phase in accordance with change in the impedance of the harmonic impedance tuning circuit 160 of the present disclosure. FIG. 7 shows a phase when the source frequency is 60 MHZ, the inductance of each of the first inductor L1 and the second inductor L2 is 10 nH, and the capacitance of the variable capacitor C1 is adjusted in several stages between 3 pF and 10 pF. In FIG. 7, the vertical axis represents phase (deg), and the horizontal axis represents frequency (MHz). The curves shown in FIG. 7 indicate simulation results for the phase in accordance with the capacitance value of the variable capacitor C1. Referring to FIG. 7, it is confirmed that the phase may be adjusted in accordance with change in the impedance of the harmonic impedance tuning circuit 160.

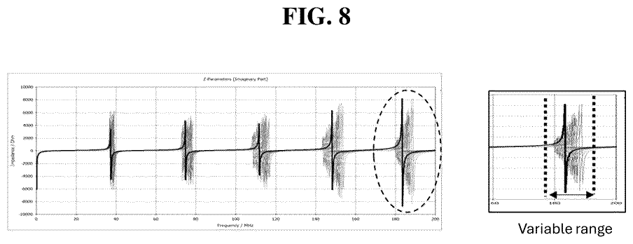

FIG. 8 shows a result of measuring the reactance component of the harmonic impedance tuning circuit 160 in accordance with frequency. In FIG. 8, the horizontal axis represents frequency, and the vertical axis represents a value obtained by measuring the reactance component in the impedance of the harmonic impedance tuning circuit 160. As shown in the right part of FIG. 8, it is confirmed that, when the capacitance of the variable capacitor C1 of the harmonic impedance tuning circuit 160 is adjusted, the curve indicating the reactance measurement value is shifted horizontally within a variable range. As described above, the impedance of the harmonic impedance tuning circuit 160 may be controlled by adjusting the capacitance of the variable capacitor C1, and as a result, the plasma distribution in the processing area of the plasma processing apparatus 1 may be controlled.

As is apparent from the above description, according to the present disclosure, plasma distribution may be controlled more precisely using harmonic components of an RF signal.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. A substrate support assembly configured to support a substrate in a plasma processing apparatus, the substrate support assembly comprising:
an electrostatic chuck configured to support the substrate using electrostatic force;
an edge ring surrounding the electrostatic chuck;
an insulating ring disposed beneath the edge ring;
an edge electrode disposed in the insulating ring;
a harmonic impedance tuning circuit connected to the edge electrode; and
an edge impedance control circuit connected to the harmonic impedance tuning circuit,
wherein the harmonic impedance tuning circuit comprises a band-stop filter having a resonance frequency equal to or higher than a harmonic frequency of a source frequency of a radio-frequency (RF) signal.

2. The substrate support assembly as claimed in claim 1, wherein the resonance frequency of the harmonic impedance tuning circuit is set to be equal to or higher than a third-order harmonic frequency.

3. The substrate support assembly as claimed in claim 1, wherein the harmonic impedance tuning circuit comprises:
a first inductor connected to a path between the edge electrode and the edge impedance control circuit; and
a second inductor and a variable capacitor connected between a ground and a node between the first inductor and the edge electrode.

4. The substrate support assembly as claimed in claim 3, wherein the second inductor and the variable capacitor are connected in series to each other.

5. The substrate support assembly as claimed in claim 4, wherein the first inductor has inductance set to 10 nH or less,
wherein the second inductor has inductance set to 10 nH or less, and
wherein the variable capacitor has capacitance set to 10 pF or less.

6. The substrate support assembly as claimed in claim 4, wherein the variable capacitor is configured as a vacuum variable capacitor (VVC).

7. The substrate support assembly as claimed in claim 4, wherein the variable capacitor is configured to change pass rates and phases of the RF signal and first-order and second-order harmonic components of the RF signal.

8. A plasma control method performed by a substrate support assembly in a plasma processing apparatus, wherein the substrate support assembly comprises:
an electrostatic chuck configured to support a substrate using electrostatic force;
an edge ring surrounding the electrostatic chuck;
an insulating ring disposed beneath the edge ring;
an edge electrode disposed in the insulating ring;
a harmonic impedance tuning circuit connected to the edge electrode; and
an edge impedance control circuit connected to the harmonic impedance tuning circuit,
wherein the harmonic impedance tuning circuit comprises a band-stop filter having a resonance frequency equal to or higher than a harmonic frequency of a source frequency of an RF signal, and
wherein the plasma control method comprises:
controlling plasma distribution in an edge area using the edge impedance control circuit; and
controlling plasma distribution in a central area using the harmonic impedance tuning circuit.

9. The plasma control method as claimed in claim 8, wherein the resonance frequency of the harmonic impedance tuning circuit is set to be equal to or higher than a third-order harmonic frequency.

10. The plasma control method as claimed in claim 8, wherein the harmonic impedance tuning circuit comprises:
a first inductor connected to a path between the edge electrode and the edge impedance control circuit; and
a second inductor and a variable capacitor connected between a ground and a node between the first inductor and the edge electrode.

11. The plasma control method as claimed in claim 10, wherein the second inductor and the variable capacitor are connected in series to each other.

12. The plasma control method as claimed in claim 11, wherein the first inductor has inductance set to 10 nH or less,
wherein the second inductor has inductance set to 10 nH or less, and
wherein the variable capacitor has capacitance set to 10 pF or less.

13. The plasma control method as claimed in claim 11, wherein the variable capacitor is configured as a vacuum variable capacitor (VVC).

14. The plasma control method as claimed in claim 11, wherein the variable capacitor is configured to change pass rates and phases of the RF signal and first-order and second-order harmonic components of the RF signal.

15. A plasma processing apparatus comprising:
a process chamber comprising a processing space defined therein;
a substrate support assembly configured to support a substrate in the processing space;
a gas supply member configured to supply a process gas to the processing space; and
an RF power supply configured to supply an RF signal so as to excite the process gas to a plasma state,
wherein the substrate support assembly comprises:
an electrostatic chuck configured to support the substrate using electrostatic force;
an edge ring surrounding the electrostatic chuck;
an insulating ring disposed beneath the edge ring;
an edge electrode disposed in the insulating ring;
a harmonic impedance tuning circuit connected to the edge electrode; and
an edge impedance control circuit connected to the harmonic impedance tuning circuit, and
wherein the harmonic impedance tuning circuit comprises a band-stop filter having a resonance frequency equal to or higher than a third-order harmonic frequency of a source frequency of the RF power supply.

16. The plasma processing apparatus as claimed in claim 15, wherein the harmonic impedance tuning circuit comprises:
a first inductor connected to a path between the edge electrode and the edge impedance control circuit; and
a second inductor and a variable capacitor connected between a ground and a node between the first inductor and the edge electrode.

17. The plasma processing apparatus as claimed in claim 16, wherein the second inductor and the variable capacitor are connected in series to each other.

18. The plasma processing apparatus as claimed in claim 17, wherein the first inductor has inductance set to 10 nH or less,
wherein the second inductor has inductance set to 10 nH or less, and
wherein the variable capacitor has capacitance set to 10 pF or less.

19. The plasma processing apparatus as claimed in claim 17, wherein the variable capacitor is configured as a vacuum variable capacitor (VVC).

20. The plasma processing apparatus as claimed in claim 17, wherein the variable capacitor is configured to change pass rates and phases of the RF signal and first-order and second-order harmonic components of the RF signal.
